(19) United States
(12) Patent Application Publication
(10) Pub. No.: US 2026/0141957 A1
(43) Pub. Date: May 21, 2026

(54) MEMORY DEVICE AND ERASE METHOD THEREOF

(71) Applicant: Samsung Electronics Co., Ltd., Suwon-si (KR)

(72) Inventors: Myung Uk PARK, Suwon-si (KR); Sukkang SUNG, Suwon-si (KR); Cheon An LEE, Suwon-si (KR); Ik-Hyung JOO, Suwon-si (KR)

(21) Appl. No.: 19/374,902

(22) Filed: Oct. 30, 2025

(30) Foreign Application Priority Data
Nov. 20, 2024 (KR) 10-2024-0166470

(51) Int. Cl. G11C 16/16; G11C 16/04; G11C 16/08; G11C 16/32

(52) U.S. Cl. CPC G11C 16/16; G11C 16/0433; G11C 16/08; G11C 16/32

(57) ABSTRACT

A memory device includes a memory cell array including a plurality of memory blocks, a plurality of pass transistors connected between a plurality of local lines included in the plurality of memory blocks, a plurality of selection signal lines connected to two or more local lines corresponding to an identical level among the plurality of local lines, and an address decoder configured to apply a block selection voltage to a block word line connected to a gate of each of the plurality of pass transistors, and the address decoder is configured to apply a first voltage to the block word line of an unselected memory block among the plurality of memory blocks.

### CROSS-REFERENCE TO RELATED APPLICATIONS

This application claims the benefit of Korean Patent Application No. 10-2024-0166470, filed on Nov. 20, 2024, in the Korean Intellectual Property Office, the disclosure of which is incorporated herein by reference in its entirety.

### BACKGROUND

A semiconductor memory device is memory implemented using a semiconductor, such as silicon (Si), germanium (Ge), gallium arsenide (GaAs), and indium phosphide (InP). The semiconductor memory device is largely divided into a volatile memory device and a nonvolatile memory device.

The volatile memory device is a memory device that loses stored data when power supply is interrupted. The volatile memory device includes static random-access memory (SRAM), dynamic RAM (DRAM), synchronous DRAM (SDRAM), and the like. The nonvolatile memory device is a memory device that maintains stored data even when power supply is interrupted. The nonvolatile memory device includes read-only memory (ROM), programmable ROM (PROM), electrically programmable ROM (EPROM), electrically erasable and programmable ROM (EEPROM), flash memory, phase-change RAM (PRAM), magnetic RAM (MRAM), resistive RAM (RRAM), ferroelectric RAM (FRAM), and the like. The flash memory is largely divided into a NOR type and a NAND type.

### SUMMARY

In general, the present disclosure is directed toward a memory device and an erase method thereof.

According to some implementations, the present disclosure is directed to a memory device that includes a memory cell array including a plurality of memory blocks and a plurality of local lines, a plurality of pass transistors connected to the plurality of local lines, a plurality of selection signal lines connected to two or more local lines of the plurality of local lines, the two or more local lines correspond to a same level, and an address decoder configured to apply a first block selection voltage to a block word line, the block word line may be connected to a gate of each pass transistor of the plurality of pass transistors in an unselected memory block among the plurality of memory blocks.

According to some implementations, the address decoder is configured to apply a second block selection voltage to a block word line of a selected memory block among the plurality of memory blocks, and a value of the first voltage may be different from a value of the second voltage.

According to some implementations, based on the value of the first block selection voltage being greater than the value of the second block selection voltage, the address decoder is configured to float a plurality of memory cells included in the selected memory block upon a first selection voltage being greater than or equal to the value of the second block selection voltage applied to the plurality of selection signal lines, or the address decoder is configured to float the plurality memory cells in the selected memory block and a plurality of memory cells included in the unselected memory block upon a second selection voltage being greater than or equal to the value of the first block selection voltage applied to the plurality of selection signal lines.

According to some implementations, based on the value of the first selection block voltage being less than the value of the second selection block voltage, the address decoder is configured to float a plurality of memory cells included in the unselected memory block upon a first selection voltage being greater than or equal to the value of the first selection block voltage applied to the plurality of selection signal lines, or the address decoder is configured to float a plurality of memory cells included in the selected memory block and the plurality of memory cells included in the unselected memory block upon a second selection voltage being greater than or equal to the value of the second selection block voltage applied to the plurality of selection signal lines.

According to some implementations, upon an erase voltage being applied to a bit line of the plurality of memory blocks, the address decoder is configured to apply the first selection voltage, based on a control timing of each of a plurality of sub-word lines among the plurality of local lines included in the unselected memory block, to the plurality of selection signal lines that correspond to the plurality of sub-word lines.

According to some implementations, the control timing may be based on the levels at which the plurality of sub-word lines are located.

According to some implementations, the control timing may be based on a distance from either a first end or a second end of a cell string included in the unselected memory block.

According to some implementations, the address decoder is configured to apply the first selection voltage so that a memory cell of a sub-word line with a shortest distance from an end of the cell string is floated first.

According to some implementations, the plurality of sub-word lines are configured such that voltage values of the plurality of sub-word lines may decrease as the distance from either end of the cell string increases.

According to some implementations, the address decoder is configured to set voltage values of a plurality of main word lines among the plurality of local lines to 0.

According to some implementations, the present disclosure is directed to an erase method of a memory device, the erase method including applying, by a processor, a first voltage to a block word line of an unselected memory block among a plurality of memory blocks, applying, by a processor, an erase voltage to a bit line of the plurality of memory blocks, and based on a control timing of each of a plurality of sub-word lines among a plurality of local lines in the memory blocks, applying, by a processor, a selection voltage to a plurality of selection signal lines corresponding to the plurality of sub-word lines.

According to some implementations, a value of the first voltage may be different from a value of a second voltage applied to the block word line of a selected memory block among the plurality of memory blocks.

According to some implementations, applying the selection voltage may include, when the value of the first voltage is greater than the value of the second voltage, floating a plurality of memory cells included in the selected memory block by applying a first selection voltage to the plurality of selection signal lines, the first selection voltage is greater than or equal to the second voltage, or floating the plurality of memory cells in the selected memory block and a plurality of memory cells in the unselected memory block by applying a second selection voltage to the plurality of selection signal lines, the second selection voltage is greater than or equal to the first voltage.

According to some implementations, applying the selection voltage may include, when the value of the first voltage is less than the value of the second voltage, floating a plurality of memory cells in the unselected memory block by applying a first selection voltage to the plurality of selection signal lines, the first selection voltage greater than or equal to the first voltage, or floating a plurality of memory cells in the selected memory block and the plurality of memory cells in the unselected memory block by applying a second selection voltage to the plurality of selection signal lines, the second selection voltage is greater than or equal to the second voltage.

According to some implementations, the control timing may be based on levels at which the plurality of sub-word lines are located.

According to some implementations, the control timing may be based on a distance from either a first end or a second end of a cell string included in the plurality of memory blocks.

According to some implementations, the selection voltage may be applied so that a memory cell of a sub-word line with a shortest distance from either the first end or the second end of the cell string is floated first.

According to some implementations, voltage values of the plurality of sub-word lines may decrease as the distance from either the first end or the second end of the cell string increases.

According to some implementations, the present disclosure is directed to a memory device that includes a memory cell array including a plurality of memory blocks including a plurality of cell strings stacked on a substrate and a peripheral circuit configured to perform control of the memory cell array, and the peripheral circuit may be configured to apply a first voltage to a block word line of an unselected memory block among the plurality of memory blocks, the peripheral circuit may be configured to apply a second voltage to a block word line of a selected memory block among the plurality of memory blocks, and a value of the first voltage may be different from a value of the second voltage.

According to some implementations, a plurality of sub-word lines among a plurality of local lines included in the plurality of memory blocks may be configured such that voltages of the plurality of sub-word lines may decrease as a distance from an uppermost end of the plurality of cell strings or a distance from the substrate increases.

According to some implementations, it is possible to control multiple signals for a selected memory block and an unselected memory block.

Further, according to some implementations, it is possible to effectively decrease an area of a pass transistor included in memory blocks.

### BRIEF DESCRIPTION OF THE DRAWINGS

Example implementations will be more clearly understood from the following detailed description, taken in conjunction with the accompanying drawings.

FIG. 1 is a diagram of an example of a memory system according to some implementations.

FIG. 2 is a diagram of an example of a memory device according to some implementations.

FIG. 3 is a diagram of an example of a memory cell array according to some implementations.

FIGS. 4A and 4B are diagrams for illustrating examples of voltages applied to a selected memory block and an unselected memory block during an erase operation according to some implementations.

FIG. 5 is a diagram for illustrating an example of an erase method of a memory device according to some implementations.

FIG. 6 is a timing diagram of an example of a voltage applied to a local line according to some implementations.

FIGS. 7 and 8 are diagrams of examples of voltage gradients of local lines according to some implementations.

FIG. 9 is a flowchart of an example of an erase method of a memory device according to some implementations.

FIG. 10 is a block diagram of an example of a memory device according to some implementations.

### DETAILED DESCRIPTION

Hereinafter, example implementations will be explained in detail with reference to the accompanying drawings.

Throughout the present disclosure, when a part is described as “comprising or including” a component, it does not exclude another component but may further include another component unless otherwise stated. Further, terms such as “. . . unit,” “. . . part,” and “. . . module” described in the specification mean a unit that processes at least one function or operation, which may be implemented as hardware, software, or a combination thereof.

While such terms as first and/or second may be used to describe various elements, such elements should not be limited by the above terms. The terms may be used to distinguish one element from another, and for example, without departing from the scope of the present disclosure, a first element may be referred to as a second element, and similarly, a second element may be referred to as a first element.

When it is described that an element is “coupled” or “connected” to another element, it should be understood that the element may be directly coupled or connected to another element, and an intervening element may also be present in between. In contrast, when it is described that an element is “directly coupled” or “directly connected” to another element, it should be understood that no intervening element is present in between. Other expressions for describing a relationship between elements, such as “between” and “directly between” or “adjacent to” and “directly adjacent to,” are to be construed similarly.

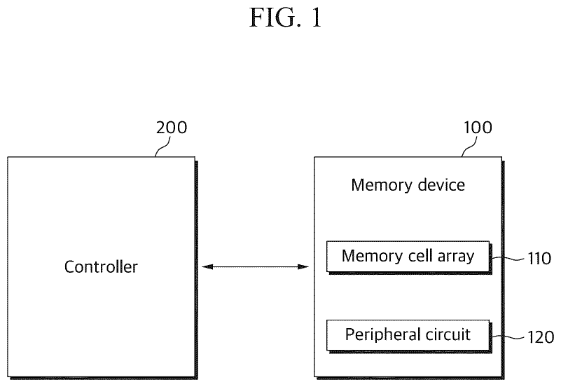

FIG. 1 is a diagram of an example of a memory system according to some implementations. In FIG. 1, the memory system includes a memory device 100 and a controller 200. The memory device 100 may operate in response to control by the controller 200. The memory device 100 may include a memory cell array 110 having a plurality of memory blocks. According to some implementations, the memory device 100 may be a flash memory device.

The memory device 100 may be configured to receive a command and an address from the controller 200 and access an area selected by the address in the memory cell array 110. In other words, the memory device 100 may perform an internal operation corresponding to the command of the controller 200 for the area selected by the address.

The memory device 100 may include a peripheral circuit 120 for performing the internal operation. As an example, the peripheral circuit 120 may perform control of the memory cell array 110. For example, the peripheral circuit 120 may apply a first voltage to a plurality of block word lines of an unselected memory block among the plurality of memory blocks of the memory cell array 110. This will be described below.

The memory device 100 may perform a program operation, a read operation, and an erase operation. During the program operation, the memory device 100 may program data in the area selected by the address. During the read operation, the memory device 100 may read data from the area selected by the address. During the erase operation, the memory device 100 may erase data stored in the area selected by the address.

The controller 200 may control the memory device 100 to perform the program operation, the read operation, or the erase operation. During the program operation, the controller 200 may provide a program command, an address, and data to the memory device 100. During the read operation, the controller 200 may provide a read command and an address to the memory device 100. During the erase operation, the controller 200 may provide an erase command and an address to the memory device 100.

According to some implementations, the controller 200 may include components, such as random-access memory (RAM), a processing unit, a host interface, and a memory interface. The RAM may be used as at least one of working memory of the processing unit, cache memory between the memory device 100 and a host, and buffer memory between the memory device 100 and the host. The processing unit may control overall operations of the controller 200.

The host interface may include a protocol for performing a data exchange between the host and the controller 200. For example, the controller 200 may be configured to communicate with the host through at least one of various interface protocols, such as a universal serial bus (USB) protocol, a multimedia card (MMC) protocol, a peripheral component interconnection (PCI) protocol, a PCI-express (PCI-E) protocol, an advanced technology attachment (ATA) protocol, a serial-ATA protocol, a parallel-ATA protocol, a small computer small interface (SCSI) protocol, an enhanced small disk interface (ESDI) protocol, an integrated drive electronics (IDE) protocol, and a private protocol. The memory interface may interface with the memory device 100. As an example, the memory interface may include a NAND interface or a NOR interface.

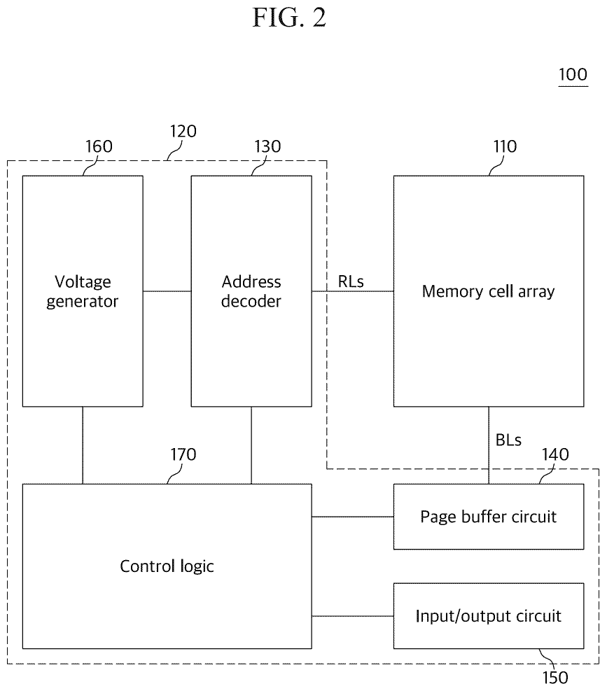

FIG. 2 is a diagram of an example of a memory device according to some implementations. The features described with respect to FIG. 2 may also be applied to the features described with respect to FIG. 1.

In FIG. 2, a memory device 100 may include the peripheral circuit 120 may include an address decoder 130, a page buffer circuit 140, an input/output circuit 150, a voltage generator 160, and a control logic 170.

According to some implementations, a memory cell array 110 may include a plurality of memory blocks. Each of the plurality of memory blocks may have a two-dimensional structure or a three-dimensional structure. In a memory block having the two-dimensional structure (or a horizontal structure), memory cells may be formed in a horizontal direction to a substrate, and in a memory block having the three-dimensional structure (or a vertical structure), memory cells may be formed in a vertical direction to the substrate. In this case, the plurality of memory blocks having the three-dimensional structure may include a plurality of cell strings formed as stacked on the substrate.

The address decoder 130 may be connected to the memory cell array 110 through row lines RLs. The row lines RLs may include string selection lines (SSLs), ground selection lines (GSLs), word lines (WLs), dummy word lines (DWLs), and gate induced drain leakage lines (GIDLs).

During an erase operation, the address decoder 130 may select a memory block for the erase operation to be performed among the plurality of memory blocks in response to control by the control logic 170. In addition, during the erase operation, the address decoder 130 may float at least one of the row lines RLs in response to control by the control logic 170.

The page buffer circuit 140 may be connected to the memory cell array 110 through bit lines BLs. The page buffer circuit 140 may temporarily store data to be programmed in a selected page or data read from the selected page.

The input/output circuit 150 may be connected internally to the page buffer circuit 140 through data lines (DLs) and connected externally to a memory controller through input/output lines.

The voltage generator 160 may generate various voltages required to operate the memory device 100. For example, the voltage generator 160 may be configured to generate various voltages provided to the row lines RLs during a program operation, an erase operation, or a read operation, such as a plurality of program voltages, a plurality of erase voltages, and a plurality of read voltages. In this case, for example, the erase voltage may be provided to a common source line and/or a bit line during the erase operation.

As an example, row line voltages may be provided to row lines during the erase operation. Specifically, the row line voltages may be provided to global lines (a global string selection line, a global word line, a global pass gate, and the like) during the erase operation, and the erase voltage output on the global lines may be transferred to local lines (a string selection line, a word line, a dummy word line, a drain selection line, a ground selection line, a GIDL line, a pass gate, and the like) of a selected memory block. In this case, the voltage generator 160 may generate the erase voltage and the row line voltages through a step-up manner of gradually increasing to a target voltage.

The control logic 170 may control overall operations of the memory device 100. According to an example embodiment, the control logic 170 may apply the erase voltage to a predetermined transistor through the bit line connected to a drain or the common source line connected to a source. In this case, before the erase voltage is applied to the predetermined transistor, a gate line of the corresponding transistor may be pre-charged and the gate line of the corresponding transistor may be floated. Subsequently, as the erase voltage is provided to the drain or the source of the corresponding transistor, a voltage level of the gate line of the corresponding transistor coupled to a channel may increase.

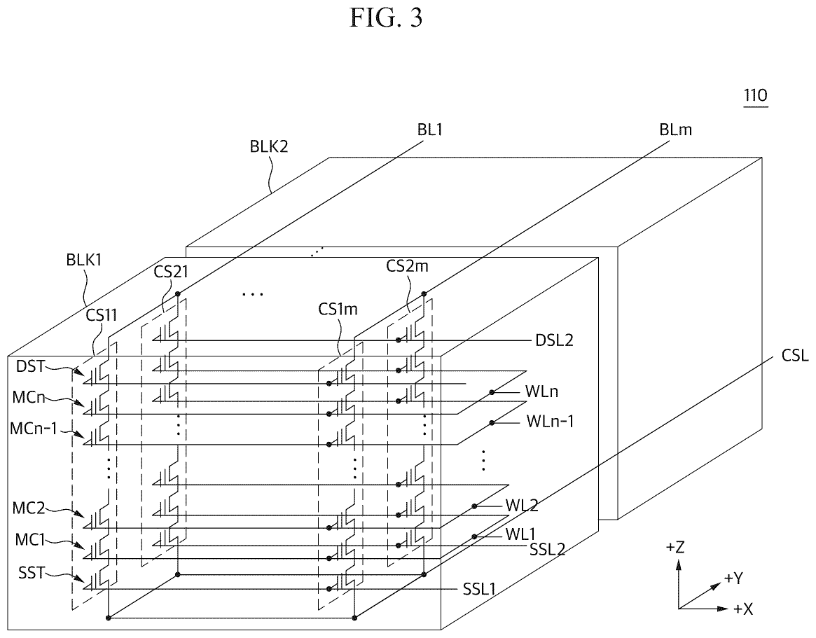

FIG. 3 is a diagram of an example of a memory cell array according to some implementations. In FIG. 3, the memory cell array 110 may include a plurality of memory blocks (BLK1 to BLKz). In FIG. 3, an internal configuration of a first memory block BLK1 alone is illustrated for convenience of description and internal configurations of other memory blocks (BLK2 to BLKz) are omitted, but second to z-th memory blocks (BLK2 to BLKz) may also be configured similarly to the first memory block BLK1. Further, in FIG. 3, the first memory block BLK1 and the second memory block BLK2 are only illustrated for convenience of description and other memory blocks (BLK3 to BLKz) are omitted, but the number of the plurality of memory blocks (BLK1 to BLKz) is not limited thereto.

The first memory block BLK1 may include a plurality of cell strings CS11 to CS1m, CS21 to CS2m. Each of the plurality of cell strings CS11 to CS1m, CS21 to CS2m may extend along a +Z direction. A Z direction may be a direction perpendicular to a substrate. Accordingly, in other words, the plurality of cell strings CS11 to CS1m, CS21 to CS2m may be formed as stacked on the substrate. Within the first memory block BLK1, m cell strings may be arranged in a +X direction. An X direction may be a direction parallel to the substrate and perpendicular to a direction (for example, a Y direction) in which a bit line is extended. However, this is for convenience of description, and the number of the plurality of cell strings and the directions in which the plurality of cell strings are arranged or extended may be changed depending on various implementations.

According to some implementations, each of the plurality of cell strings CS11 to CS1m, CS21 to CS2m may include at least one source selection transistor SST, first to n-th memory cells MC1 to MCn, and at least one drain selection transistor DST.

The source selection transistor SST of each cell string may be connected between a common source line CSL and the memory cells MC1 to MCn. In this case, source selection transistors of cell strings arranged in an identical row may be connected to an identical source selection line. For example, source selection transistors of the cell strings CS11 to CS1m arranged in a first row may be connected to a first source selection line SSL1, and source selection transistors of the cell strings CS21 to CS2m arranged in a second row may be connected to a second source selection line SSL2. For another example, the source selection transistors of the cell strings CS11 to CS1m, CS21 to CS2m may also be connected to one source selection line in common. The first to n-th memory cells MC1 to MCn of each cell string may be connected in series between the source selection transistor SST and the drain selection transistor DST. Gates of the first to n-th memory cells MC1 to MCn may be connected to first to n-th word lines WL1 to WLn, respectively.

According to some implementations, at least one of the first to n-th memory cells MC1 to MCn may be used as a dummy memory cell. When the memory block BLK1 includes the dummy memory cell, a voltage or a current of a corresponding cell string may be stably controlled, and accordingly, reliability of data stored in the memory block BLK1 may be improved.

The drain selection transistor DST of each cell string may be connected between a corresponding bit line and the memory cells MC1 to MCn. Drain selection transistors of cell strings arranged in a row direction (for example, the X direction) may be connected to a drain selection line extending in the row direction. Drain selection transistors of the cell strings CS11 to CS1m of the first row may be connected to a first drain selection line (DSL1), and drain selection transistors of the cell strings CS21 to CS2m of the second row may be connected to a second drain selection line DSL2.

In FIGS. 2 and 3, while an erase operation is performed, the voltage generator 160 may generate an erase voltage based on control by the control logic 170, and the address decoder 130 may apply the erase voltage generated in the voltage generator 160 to the common source line CSL of the memory cell array 110 based on control by the control logic 170. In this case, the source selection transistor SST and the drain selection transistor DST may be controlled to be in a floating state.

Subsequently, a potential level of a channel may increase based on a potential level of the common source line CSL, and source selection lines and drain selection lines connected to multiple source selection transistors and drain selection transistors in the floating state may increase in potential levels based on the potential level of the channel by a coupling phenomenon.

In this case, data stored in the first to n-th memory cells MC1 to MCn may be erased due to the increased potential level of the channel. In other words, due to Fowler-Nordheim (FN) tunneling, electrons stored in charge storage layers of the first to n-th memory cells MC1 to MCn may be de-trapped by the potential of the channel. Specifically, the electrons stored in the charge storage layers of the first to n-th memory cells MC1 to MCn may exit to the channel to be de-trapped based on a difference between potential levels of the word lines WL1 to WLn having the increased potential level of the channel and a ground level, or the electrons stored in the charge storage layers may be de-trapped as a hot hole generated in the channel flows into the charge storage layers of the first to n-th memory cells MC1 to MCn. In this case, the first to n-th word lines WL1 to WLn may maintain the ground level or change from the floating state to the ground level.

According to some implementations, after the data of the first to n-th memory cells MC1 to MCn is erased by the erase operation, the address decoder 130 may block an erase voltage (Verase) applied to the common source line CSL and discharge the potential of the common source line CSL.

The memory block BLK1 may further include a plurality of pass transistors connected between a plurality of local lines. A block word line may be connected to a gate of each of the plurality of pass transistors. Hereinafter, a principle by which an erase operation for the plurality of local lines is performed by turning on or turning off the plurality of pass transistors based on a block selection voltage applied to the block word line is described.

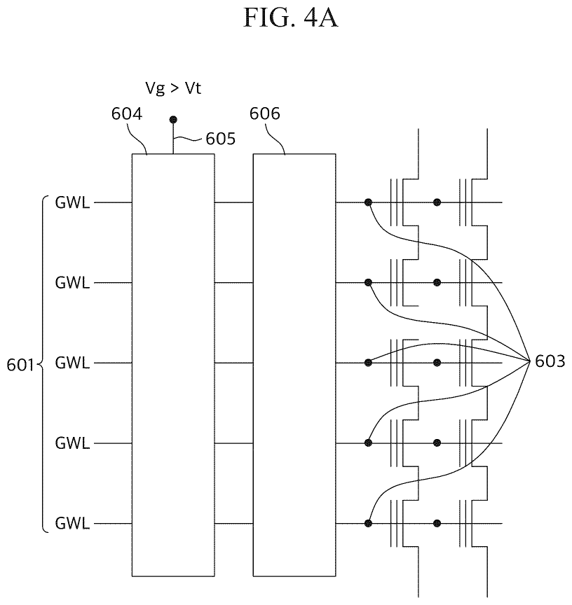

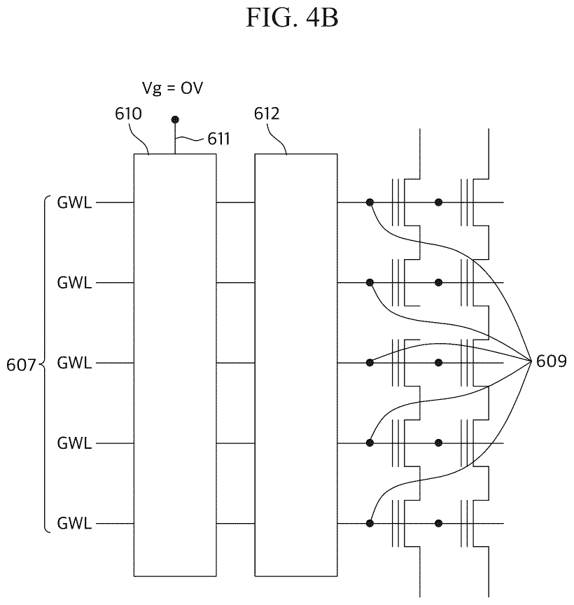

FIGS. 4A and 4B are diagrams for illustrating examples of voltages applied to a selected memory block and an unselected memory block during an erase operation according to some implementations. FIG. 4A is a diagram illustrating an example of a voltage applied to a selected memory block according to some implementations. In FIG. 4A, in the selected memory block, while an erase operation is performed, an address decoder may apply a block selection voltage Vg greater than a threshold voltage Vt of a pass transistor to a block word line 605 so that the pass transistor is turned on. In this case, since 0 volt (V) is applied to global word lines 601 and the pass transistor is turned on, 0 V may be transferred to local lines 603.

FIG. 4B is a diagram illustrating an example of a voltage applied to an unselected memory block according to some implementations. In FIG. 4B, in the unselected memory block, since a voltage of 0 V (Vg=0V) is applied to global word lines 607 and a block word line 611 connected to a pass transistor through the address decoder, the pass transistor may be in a turned-off state, and local lines 609 may be floated.

In FIGS. 4A and 4B, the selected memory block and the unselected memory block may include selection switch circuits 606, 612. In this case, the selection switch circuit 606 of the selected memory block and the selection switch circuit 612 of the unselected memory block may be connected. Specifically, the selection switch circuit 606 may include a plurality of selection signal lines connected to each of a plurality of local lines 603 of the selected memory block, and the selection switch circuit 612 may include a plurality of selection signal lines connected to each of the local lines 609 of the unselected memory block. In this case, a plurality of selection signal lines of the selected memory block and a plurality of selection signal lines of the unselected memory block may be connected. For example, the plurality of selection signal lines may be connected to two or more local lines corresponding to an identical level among a plurality of local lines included in the selected memory block and the unselected memory block.

According to some implementations, assuming that the block selection voltage Vg greater than the threshold voltage Vt of the pass transistor is applied to the block word line 605 of the selected memory block and 0 V is applied to the block word line 611 of the unselected memory block, if a voltage less than the block selection voltage Vg is applied to the plurality of selection signal lines of the selection switch circuit 606, 0 V applied to the global word lines 601 may be transferred to the plurality of local lines 603 of the selected memory block, and the plurality of local lines 609 of the unselected memory block 609 may be floated.

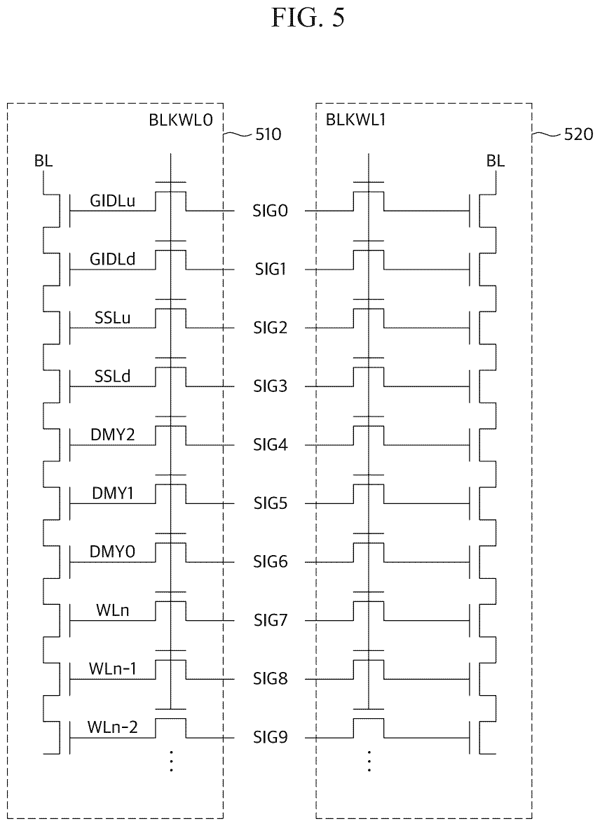

FIG. 5 is a diagram for illustrating an example of an erase method of a memory device according to some implementations. In FIG. 5, a selected memory block 510 and an unselected memory block 520 among a plurality of memory blocks are illustrated.

According to some implementations, the selected memory block 510 and the unselected memory block 520 may share one bit line BL. Accordingly, when an erase voltage is applied to the bit line BL, voltages at which the erase voltage of the bit line BL is applied to a plurality of local lines may be determined based on a block word line BLKWL0 of the selected memory block 510, a block word line BLKWL1 of the unselected memory block 520, and voltages SIG0 to SIG9 applied to a plurality of selection signal lines.

According to some implementations, an address decoder may apply a first voltage to the block word line BLKWL1 of the unselected memory block among the plurality of memory blocks. As an example, a value of the first voltage may be different from a value of a second voltage applied to the block word line BLKWL0 of the selected memory block 510 among the plurality of memory blocks 510, 520.

As an example, when the value of the first voltage is greater than the value of the second voltage, if a first selection voltage that is greater than or equal to the value of the second voltage and less than the value of the first voltage is applied to the plurality of selection signal lines, only a plurality of memory cells included in the selected memory block 510 may be floated. Further, when the value of the first voltage is greater than the value of the second voltage, if a second selection voltage greater than or equal to the value of the first voltage is applied to the plurality of selection signal lines, the plurality of memory cells included in the selected memory block 510 and a plurality of memory cells included in the unselected memory block 520 may be floated. Further, when the value of the first voltage is greater than the value of the second voltage, if a third selection voltage less than the value of the second voltage is applied to the plurality of selection signal lines, all of the plurality of memory cells included in the selected memory block 510 and the unselected memory block 520 may not be floated.

As another example, when the value of the first voltage is less than the value of the second voltage, if a first selection voltage that is greater than or equal to the value of the first voltage and less than the value of the second voltage is applied to the plurality of selection signal lines, only a plurality of memory cells included in the unselected memory block 520 may be floated. Further, when the value of the first voltage is less than the value of the second voltage, if a second selection voltage greater than or equal to the value of the second voltage is applied to the plurality of selection signal lines, both a plurality of memory cells included in the selected memory block 510 and the plurality of memory cells included in the unselected memory block 520 may be floated. Further, when the value of the first voltage is less than the value of the second voltage, if a third selection voltage less than the value of the first voltage is applied to the plurality of selection signal lines, all of the plurality of memory cells included in the selected memory block 510 and the unselected memory block 520 may not be floated.

As above, based on the first voltage and the second voltage applied to the block word line BLKWL1 of the unselected memory block 520 and the block word line BLKWL0 of the selected memory block 510, respectively, by the address decoder, multi-control of the voltages SIG0 to SIG9 applied to the plurality of selection signal lines may be performed using a difference between the first voltage and the second voltage.

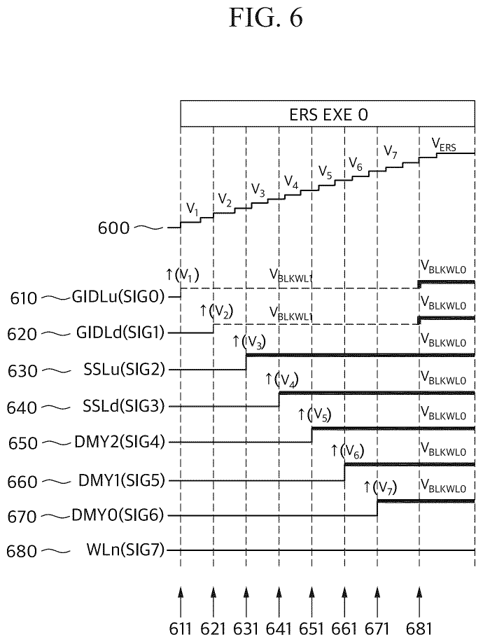

FIG. 6 is a timing diagram of an example of a voltage applied to a local line according to some implementations. According to some implementations, an erase voltage 600 applied to a bit line may increase in a step-up manner. As an example, the erase voltage 600 of the bit line may gradually increase to a target voltage, and the erase voltage 600 may be generated in a voltage generator. For example, the erase voltage 600 of the bit line may increase by 1 V for each unit time (for example, 1 millisecond (ms)) but may not increase uniformly for each unit time.

In some implementations, in which when a value of a first voltage is less than a value of a second voltage, a first selection voltage greater than or equal to the value of the first voltage is applied to a plurality of selection signal lines or a second selection voltage greater than or equal to the value of the second voltage is applied. In some implementations, in which when the value of the first voltage is greater than the value of the second voltage, a first selection voltage greater than or equal to the value of the second voltage is applied to the plurality of selection signal lines or a second selection voltage greater than or equal to the value of the first voltage is applied with reference to those described above through FIG. 5.

According to some implementations, an address decoder may apply a first selection voltage greater than or equal to the value of the first voltage to the plurality of selection signal lines based on control timings 611 to 671 of a plurality of local lines 610 to 680 included in an unselected memory block. Accordingly, a plurality of memory cells included in the unselected memory block may be floated. In this case, as the first selection voltage is applied to the plurality of selection signal lines, a local line corresponding to a selection signal line to which the voltage is applied may have a voltage increasing at a rate identical to an increasing rate of an erase voltage of a bit line from a time point at which the first selection voltage is applied.

The local line that may have an identical voltage to the erase voltage 600 of the bit line based on the control timings 611 to 671 may be sub-word lines (or special word lines) 610 to 670. The sub-word lines 610 to 670 may be the remaining lines, excluding a word line 680 for storing data from the plurality of local lines (for example, string selection lines 630, 640, the word line 680, dummy word lines 650 to 670, a drain selection line, a ground selection line, GIDL lines 610, 620, and the like). In other words, if the erase voltage 600 is applied to the bit line, based on the control timings 611 to 671 of each of a plurality of sub-word lines 610 to 670 among the plurality of local lines 610 to 680 included in the unselected memory block, the first selection voltage may be applied to the plurality of selection signal lines corresponding to the plurality of sub-word lines 610 to 670.

The control timings 611 to 671 may be determined based on levels at which the plurality of sub-word lines 610 to 670 are located. As an example, the control timings 611 to 671 may be determined based on a distance from either end of a cell string included in the unselected memory block. For the plurality of sub-word lines 610 to 670 illustrated in FIG. 6 as an example, the control timings 611 to 671 of each of the plurality of sub-word lines 610 to 670 may be delayed sequentially, from an upper GIDL line (GIDLu) 610 with a shortest distance from either end of the cell string to a lowermost dummy word line (DMY0) 670 with a longest distance from either end of the cell string. Accordingly, the control timings 611 to 671 may be earlier in an order of the control timing 611 of the upper GIDL line (GIDLu) 610, the control timing 621 of a lower GIDL line (GIDLd) 620, the control timing 631 of an upper string selection line (SSLu) 630, the control timing 641 of a lower string selection line (SSLd) 640, the control timing 651 of an uppermost dummy word line (DMY2) 650, the control timing 661 of a middle dummy word line (DMY1) 660, and the control timing 671 of the lowermost dummy word line (DMY0) 670.

The first selection voltage may be applied so that a memory cell of a sub-word line with a shortest distance from either end of the cell string among the sub-word lines 610 to 670 is floated first. For example, based on the control timings 611 to 671 of each of the plurality of sub-word lines 610 to 670, the address decoder may apply the first selection voltage to the plurality of selection signal lines corresponding to the plurality of sub-word lines 610 to 670 in order of distance from either end of the cell string included in the unselected memory block. Subsequently, as described above, memory cells of the plurality of sub-word lines 610 to 670 of the unselected memory block may be floated in order of distance from either end of the cell string, starting from the shortest.

Such operation timing is illustrated in FIG. 6. For example, it is assumed that the erase voltage 600 of the bit line increases to 0, V₁, V₂, V₃, V₄, V₅, V₆, V₇, and V_{ERS} for each unit time of 1 ms. When the address decoder applies the first selection voltage to a selection signal line corresponding to the upper GIDL line 610 at the control timing 611 of the upper GIDL line 610, the corresponding control timing 611 first may be coupled to the erase voltage 600 of the bit line, and a voltage less than the erase voltage 600 of the bit line by V₁ may be applied to the upper GIDL line 610. Similarly, when the address decoder applies the first selection voltage to a selection signal line corresponding to the lower GIDL line 620 at the control timing 621 of the lower GIDL line 620, the corresponding control timing 621 first may be coupled to the erase voltage 600 of the bit line, and a voltage less than the erase voltage 600 of the bit line by V₂ may be applied to the lower GIDL line 620. As above, as the address decoder applies the first selection voltage to selection signal lines sequentially, when the address decoder applies the first selection voltage to a selection signal line corresponding to the lowermost dummy word line 670 at the control timing 671 of the lowermost dummy word line 670, the corresponding control timing 671 first may be coupled to the erase voltage 600 of the bit line, and a voltage less than the erase voltage 600 of the bit line by V₇ may be applied to the lowermost dummy word line 670.

According to some implementations, a second selection voltage greater than or equal to the value of the second voltage may be applied to the plurality of selection signal lines corresponding to the sub-word lines 610 to 670 based on control timings (hereinafter referred to as “second control timings”) 631 to 681 of each of the plurality of sub-word lines 610 to 670 included in a selected memory block. In this case, as described above, when the second selection voltage is applied to the plurality of selection signal lines, memory cells of the sub-word lines 610 to 670 of both the selected memory block and the unselected memory block may be floated.

Accordingly, the address decoder may apply a voltage greater than or equal to the value of the first voltage, based on the control timings 611 to 671 of each of the plurality of sub-word lines of the unselected block, to the plurality of selection signal lines corresponding thereto and apply a voltage greater than or equal to the value of the second voltage, based on the second control timings 631 to 681 of each of the plurality of sub-word lines of the selected block, to the plurality of selection signal lines corresponding thereto. In this case, at the control timings 631 to 671 identical to the second control timings 631 to 681, the address decoder may apply the second selection voltage to the plurality of selection signal lines corresponding thereto. Further, at the control timings 611, 621 not identical to the second control timings 631 to 681, the address decoder may apply the first selection voltage to the plurality of selection signal lines corresponding thereto, and at the second control timing 681, apply the second selection voltage to the plurality of selection signal lines corresponding thereto.

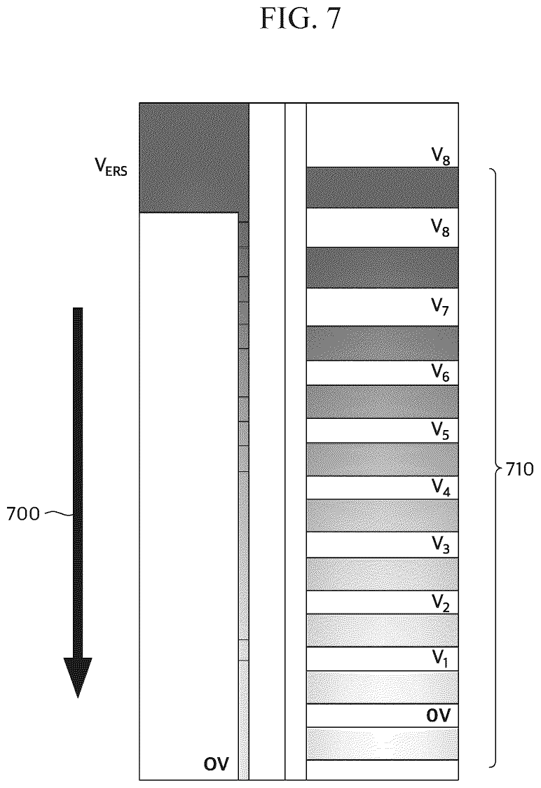

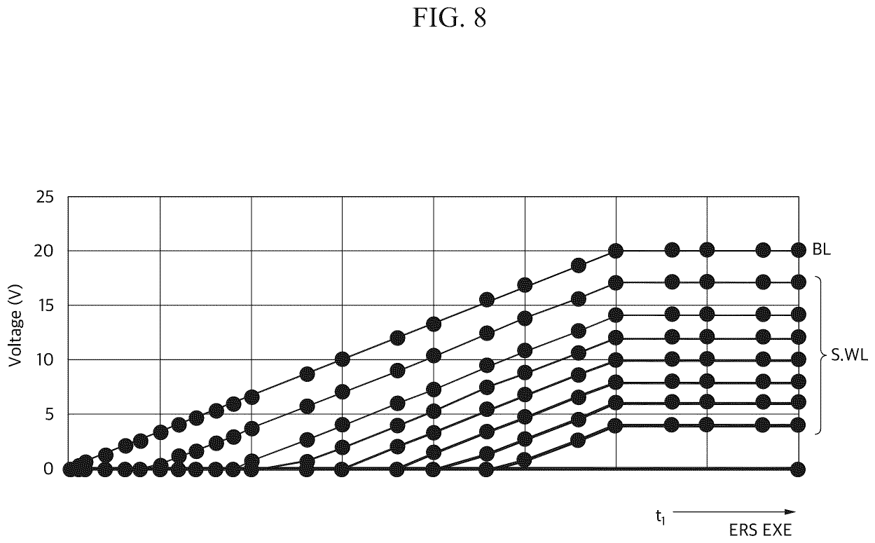

FIGS. 7 and 8 are diagrams of examples of voltage gradients of local lines according to some implementations. In FIG. 7, gradients of voltages applied to a plurality of local lines according to example embodiments described above are illustrated.

According to some implementations, by programming voltages of a plurality of local lines 710 including a plurality of sub-word lines, values of erase voltages of the plurality of local lines 710 may decrease as a distance from either end of a cell string is longer 700.

Meanwhile, a manner of forming voltage gradients of the sub-word lines 710 located at a farther area from an upper surface of a substrate is described above, but some implementations of the present disclosure may also be applied to a manner of forming voltage gradients of sub-word lines (for example, the common source line CSL, dummy word lines, and the like) located at a closer area to the upper surface of the substrate. In this case, symmetrically to FIG. 7, voltages may be higher toward a lower end in the voltage gradients.

According to some implementations, voltage values of a plurality of main word lines (WLn, WLn-1, WLn-2, . . . ) among the plurality of local lines 710 may be 0. As described above, as being closer to a main word line from either end of a cell string, magnitudes of voltages applied to sub-word lines may be smaller. Therefore, as an example, voltages of the plurality of main word lines (WLn, WLn-1, WLn-2, . . . ) may be determined as 0.

Generally, as voltages of the plurality of local lines 710 become identical to a value of an erase voltage of a bit line due to floating of memory cells, a pass transistor may be required to have an area of a predetermined level or above in order for the pass transistor to handle a difference between an erase voltage V_{ERS} applied to the plurality of local lines 710 and a voltage applied to a selection signal line. However, according to the present disclosure, since the voltage difference for the pass transistor to handle greatly decreases as the voltages of the plurality of local lines 710 gradually decreases, the area of the pass transistor may be effectively reduced.

In FIG. 8, gradients of voltages applied to a plurality of local lines according to example embodiments described above are illustrated.

According to some implementations, before a start time point t1 of an erase operation ERS EXE, an erase voltage applied to a bit line BL may increase in the step-up manner. In this case, voltage gradients of a plurality of sub-word lines S. WL according to example embodiments described above may decrease as a distance from either end of a cell string is longer based on a control timing of each of the plurality of sub-word lines S. WL, and a voltage of a main word line may be determined to be 0.

Meanwhile, in FIG. 3, each of the plurality of memory blocks (BLK1 to BLKz) included in the memory cell array 110 may include a plurality of sub-memory blocks (not shown). For example, each of the plurality of memory blocks (BLK1 to BLKz) may include the plurality of sub-memory blocks (not shown) divided with respect to a word line and/or a bit line.

Specifically, as an example of the plurality of sub-memory blocks (not shown) divided with respect to the word line, when a plurality of word lines WL1 to WLn are 200, one sub-memory block may be composed of the first word line WL1 to a hundredth word line WL100, and another sub-memory block may be composed of a 101st word line WL101 to a 200th word line WL200. However, the number of sub-memory blocks included in one memory block is not limited thereto, and the sub-memory block is not necessarily divided with respect to a word line and may also be divided with respect to a bit line or a layer. In other words, each of the plurality of memory blocks (BLK1 to BLKz) may include the plurality of sub-memory blocks (not shown) according to various example embodiments.

According to some implementations, different voltages (a first voltage and a second voltage) are applied to block word lines of a selected memory block and an unselected memory block according to some implementations described above may be applied identically to the plurality of sub-memory blocks. For example, when the plurality of sub-memory blocks (not shown) is 2, a first voltage or a second voltage greater than a value of the first voltage may be applied to each sub-block word line, and in this case, by applying a voltage between the value of the first voltage and a value of the second voltage or a voltage greater than the value of the second voltage to a plurality of selection signal lines, voltage gradients of word lines of the plurality of sub-memory blocks (not shown) may be controlled. Similarly, for another example, when the plurality of sub-memory blocks (not shown) is 3, a first voltage, a second voltage greater than a value of the first voltage, or a third voltage greater than a value of the second voltage may be applied to each sub-block word line, and in this case, by applying a voltage between the value of the first voltage and the value of the second voltage, a voltage between the value of the second voltage and a value of the third voltage, or a voltage greater than the value of the third voltage to a plurality of selection signal lines, voltage gradients of word lines of the plurality of sub-memory blocks (not shown) may be controlled.

However, the implementations described above may be applied to the plurality of sub-memory blocks (not shown).

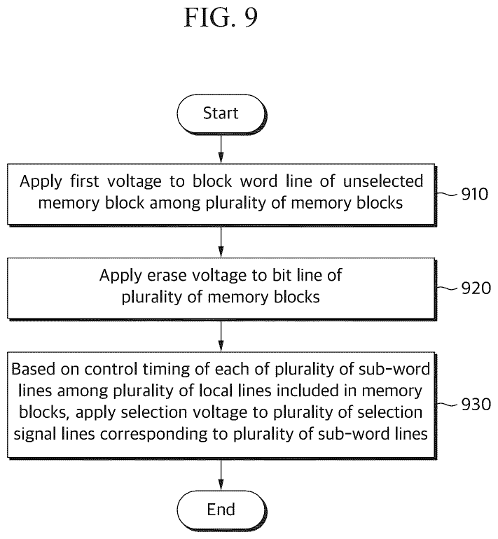

FIG. 9 is a flowchart of an example of an erase method of a memory device according to some implementations. The erase method of the memory device may be performed by a processor, and in this case, the processor may be one of elements included in the memory device. For example, the processor may be an address decoder, a voltage generator, or a control logic (or an element included therein), or the processor may be a controller outside the memory device (or an element included therein).

In FIG. 9, in operation S910, the processor may apply a first voltage to a plurality of block word lines of an unselected memory block among a plurality of memory blocks. According to some implementations, a value of the first voltage may be different from a value of a second voltage applied to a block word line of a selected memory block among the plurality of memory blocks.

In operation S920, the processor may apply an erase voltage to a bit line of the plurality of memory blocks.

In operation S930, the processor may, based on a control timing of each of a plurality of sub-word lines among a plurality of local lines included in the memory blocks, apply a selection voltage to a plurality of selection signal lines corresponding to the plurality of sub-word lines. According to some implementations, the control timing may be determined based on levels at which the plurality of sub-word lines are located. According to some implementations, the control timing may be determined based on a distance from either end of a cell string included in the plurality of memory blocks.

According to some implementations, a first selection voltage may be applied so that a memory cell of a sub-word line with a shortest distance from either end of the cell string is floated first. According to some implementations, voltage values of the plurality of sub-word lines may decrease as the distance from either end of the cell string is longer.

When the value of the first voltage is greater than the value of the second voltage, a plurality of memory cells included in the selected memory block may be floated by applying a first selection voltage greater than or equal to the value of the second voltage to the plurality of selection signal lines, or the plurality of memory cells included in the selected memory block and a plurality of memory cells included in the unselected memory block may be floated by applying a second selection voltage greater than or equal to the value of the first voltage to the plurality of selection signal lines.

When the value of the first voltage is less than the value of the second voltage, a plurality of memory cells included in the unselected memory block may be floated by applying a first selection voltage greater than or equal to the value of the first voltage to the plurality of selection signal lines, and a plurality of memory cells included in the selected memory block and the plurality of memory cells included in the unselected memory block may be floated by applying a second selection voltage greater than or equal to the value of the second voltage to the plurality of selection signal lines.

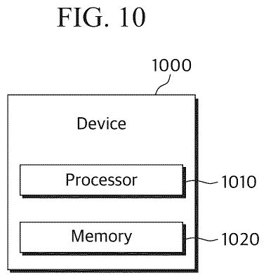

FIG. 10 is a block diagram of an example of a memory device according to some implementations. In FIG. 10, a memory device (hereinafter referred to as a “device”) 1000 may include a processor 1010 and a memory 1020. In addition, the device 1000 and the memory 1020 may be elements being identical or performing identical functions to the memory system and the memory device 100 described above through FIGS. 1 to 9.

FIG. 10 illustrates a single processor 1010, but the device 1000 may include any number of processors, and each processor may be a single-core processor or a multi-core processor, and each processor may implement a reduced instruction set computer (RISC) architecture or a complex instruction set computer (CISC) architecture (among other possibilities) and be mixed in a desired combination. In addition, the memory 1020 may be provided with a separate processor.

The memory 1020 is hardware for storing a variety of data processed within the device 1000 and may store programs for processing and controlling of the processor 1010. The memory 1020 may include random access memory (RAM), such as dynamic random access memory (DRAM) and static random access memory (SRAM), read-only memory (ROM), electrically erasable programmable read-only memory (EEPROM), CD-ROM, Blu-ray or other optical disk storage, hard disk drive (HDD), solid-state drive (SSD), or flash memory.

The processor 1010 may control overall operations of the device 1000. For example, the processor 1010 may overall control an input part (not shown), a display (not shown), a communication part (not shown), the memory 1020, and the like by executing the programs stored in the memory 1020. The processor 1010 may control the operation of the device 1000 by executing the programs stored in the memory 1020. The processor 1010 may control at least some of the operations of the device described above in FIGS. 1 to 9.

The processor 1010 may be implemented using at least one of application specific integrated circuits (ASICs), digital signal processors (DSPs), digital signal processing devices (DSPDs), programmable logic devices (PLDs), field programmable gate arrays (FPGAs), controllers, micro-controllers, microprocessors, and electrical units for performing other functions.

According to some implementations, the device 1000 may be a server. The server may be implemented as a computer device or a plurality of computer devices providing instructions, codes, files, content, services, and the like by communicating through networks.

Meanwhile, the device 1000 may further include a communication part. The communication part may include one or more components that allow wired/wireless communications with an external server or an external device. For example, the communication part may include at least one of a short-range communication part, a mobile communication part, and a broadcast reception part.

The electronic device may include a processor, a memory for storing and executing program data, a permanent storage such as a disk drive, a communication port that communicates with an external device, and a user interface device such as a touch panel, a key, and a button. Methods implemented as software modules or algorithms may be stored in a computer-readable recording medium as computer-readable codes or program instructions executable on the processor. Here, the computer-readable recording medium includes a magnetic storage medium (for example, read-only memory (ROM), random-access memory (RAM), floppy disks, and hard disks) and an optically readable medium (for example, CD-ROM and digital versatile discs (DVDs)). The computer-readable recording medium may be distributed among network-connected computer systems, so that the computer-readable codes may be stored and executed in a distributed manner. The medium may be readable by a computer, stored in a memory, and executed on a processor.

The implementations may be represented by functional block elements and various processing steps. The functional blocks may be implemented in any number of hardware and/or software configurations that perform specific functions. For example, some implementations may adopt integrated circuit configurations, such as memory, processing, logic, and/or look-up table, which may execute various functions by the control of one or more microprocessors or other control devices. Similarly to that elements may be implemented as software programming or software elements, some implementations may be implemented in a programming or scripting language such as C, C++, Java, assembler, etc., including various algorithms implemented as a combination of data structures, processes, routines, or other programming constructs. Functional aspects may be implemented in an algorithm running on one or more processors. Further, the example embodiments may adopt the existing art for electronic environment setting, signal processing, and/or data processing. Terms such as “mechanism,” “element,” “means,” and “configuration” may be used broadly and are not limited to mechanical and physical configurations. The terms may include the meaning of a series of routines of software in association with a processor or the like.

While this disclosure contains many specific implementation details, these should not be construed as limitations on the scope of what may be claimed, equivalents thereof, as well as claims to be described later. Certain features that are described in this disclosure in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

What is claimed is:

1. A memory device comprising:
a memory cell array comprising a plurality of memory blocks and a plurality of local lines;
a plurality of pass transistors connected to the plurality of local lines;
a plurality of selection signal lines connected to two or more local lines of the plurality of local lines, wherein the two or more local lines correspond to a same level; and
an address decoder configured to apply a first block selection voltage to a block word line,
wherein the block word line is connected to a gate of each pass transistor of the plurality of pass transistors in an unselected memory block among the plurality of memory blocks.

2. The memory device of claim 1,
wherein the address decoder is configured to apply a second block selection voltage to a block word line of a selected memory block among the plurality of memory blocks, and
wherein a value of the first voltage is different from a value of the second voltage.

3. The memory device of claim 2, wherein, based on the value of the first block selection voltage being greater than the value of the second block selection voltage,
the address decoder is configured to float a plurality of memory cells included in the selected memory block upon a first selection voltage being greater than or equal to the value of the second block selection voltage applied to the plurality of selection signal lines, or
the address decoder is configured to float the plurality memory cells in the selected memory block and a plurality of memory cells included in the unselected memory block upon a second selection voltage being greater than or equal to the value of the first block selection voltage applied to the plurality of selection signal lines.

4. The memory device of claim 2, wherein, based on the value of the first selection block voltage being less than the value of the second selection block voltage,
the address decoder is configured to float a plurality of memory cells included in the unselected memory block upon a first selection voltage being greater than or equal to the value of the first selection block voltage applied to the plurality of selection signal lines, or
the address decoder is configured to float a plurality of memory cells included in the selected memory block and the plurality of memory cells included in the unselected memory block upon a second selection voltage being greater than or equal to the value of the second selection block voltage applied to the plurality of selection signal lines.

5. The memory device of claim 4, wherein, upon an erase voltage being applied to a bit line of the plurality of memory blocks, the address decoder is configured to apply the first selection voltage, based on a control timing of each of a plurality of sub-word lines among the plurality of local lines included in the unselected memory block, to the plurality of selection signal lines that correspond to the plurality of sub-word lines.

6. The memory device of claim 5, wherein the control timing is based on the levels at which the plurality of sub-word lines are located.

7. The memory device of claim 6, wherein the control timing is based on a distance from either a first end or a second end of a cell string included in the unselected memory block.

8. The memory device of claim 7, wherein the address decoder is configured to apply the first selection voltage so that a memory cell of a sub-word line with a shortest distance from an end of the cell string is floated first.

9. The memory device of claim 7, wherein the plurality of sub-word lines are configured such that voltage values of the plurality of sub-word lines decrease as the distance from either end of the cell string increases.

10. The memory device of claim 9, wherein the address decoder is configured to set voltage values of a plurality of main word lines among the plurality of local lines to 0.

11. An erase method of a memory device, the erase method comprising:
applying, by a processor, a first voltage to a block word line of an unselected memory block among a plurality of memory blocks;
applying, by the processor, an erase voltage to a bit line of the plurality of memory blocks; and
based on a control timing of each of a plurality of sub-word lines among a plurality of local lines in the memory blocks, applying, by the processor, a selection voltage to a plurality of selection signal lines corresponding to the plurality of sub-word lines.

12. The erase method of claim 11, wherein a value of the first voltage is different from a value of a second voltage applied to the block word line of a selected memory block among the plurality of memory blocks.

13. The erase method of claim 12, wherein applying the selection voltage includes, when the value of the first voltage is greater than the value of the second voltage,
(i) floating a plurality of memory cells included in the selected memory block by applying a first selection voltage to the plurality of selection signal lines, wherein the first selection voltage is greater than or equal to the second voltage, or
(ii) floating the plurality of memory cells in the selected memory block and a plurality of memory cells in the unselected memory block by applying a second selection voltage to the plurality of selection signal lines, wherein the second selection voltage is greater than or equal to the first voltage.

14. The erase method of claim 12, wherein applying the selection voltage includes, when the value of the first voltage is less than the value of the second voltage,
(i) floating a plurality of memory cells in the unselected memory block by applying a first selection voltage to the plurality of selection signal lines, wherein the first selection voltage greater than or equal to the first voltage, or
(ii) floating a plurality of memory cells in the selected memory block and the plurality of memory cells in the unselected memory block by applying a second selection voltage to the plurality of selection signal lines, wherein the second selection voltage is greater than or equal to the second voltage.

15. The erase method of claim 11, wherein the control timing is based on levels at which the plurality of sub-word lines are located.

16. The erase method of claim 15, wherein the control timing is based on a distance from either a first end or a second end of a cell string included in the plurality of memory blocks.

17. The erase method of claim 16, wherein the selection voltage is applied so that a memory cell of a sub-word line with a shortest distance from either the first end or the second end of the cell string is floated first.

18. The erase method of claim 16, wherein voltage values of the plurality of sub-word lines decrease as the distance from either the first end or the second end of the cell string increases.

19. A memory device comprising:
a memory cell array including a plurality of memory blocks comprising a plurality of cell strings stacked on a substrate; and
a peripheral circuit configured to perform control of the memory cell array,
wherein the peripheral circuit is configured to apply a first voltage to a block word line of an unselected memory block among the plurality of memory blocks,
wherein the peripheral circuit is configured to apply a second voltage to a block word line of a selected memory block among the plurality of memory blocks, and
wherein a value of the first voltage is different from a value of the second voltage.

20. The memory device of claim 19, wherein a plurality of sub-word lines among a plurality of local lines included in the plurality of memory blocks are configured such that voltages of the plurality of sub-word lines decrease as a distance from an uppermost end of the plurality of cell strings or a distance from the substrate increases.
